(19) United States
(12) Patent Application Publication
(10) Pub. No.: US 2005/0040386 A1
(43) Pub. Date: Feb. 24, 2005

(54) Multiple quantum well broad spectrum gain medium and method for forming same

(76) Inventor: Fow-Sen Choa, Baltimore, MD (US)

Correspondence Address: FLESHNER & KIM, LLP, P.O. BOX 221200, CHANTILLY, VA, 20153, US

(21) Appl. No.: 10/478,778

(22) PCT Filed: Feb. 20, 2002
(86) PCT No.: PCT/US02/04867

Related U.S. Application Data
(60) Provisional application No. 60/269,267, filed on Feb. 20, 2001.

(51) Int. Cl. H01L 29/06; H01L 31/0328; H01L 29/24

(52) U.S. Cl. 257/14; 257/22; 257/21; 257/102

(57) ABSTRACT

A broadband medium (100) for a laser (300) having multiple quantum wells (130).

This application claims priority to U.S. Provisional Application No. 60/269,267, filed Feb. 20, 2001, which is hereby incorporated by reference in its entirety.

### BACKGROUND OF THE INVENTION

1. Field of the Invention

This invention relates to semiconductor optical gain media and, more particularly, to a multiple quantum well semiconductor optical gain medium that exhibits a broad gain spectrum.

2. Background of the Related Art

Broadly tunable optical devices, such as broadly tunable semiconductor lasers and broadband wavelength converters, are desired for various optical communication applications, such as optical networking, wavelength-division-multiplexing and other telecommunications applications.

Multiple quantum well (MQW) gain materials have been used because of their relatively broad gain spectra. However, there is a continuing need for broader tuning ranges than prior art MQW materials offer.

The above references are incorporated by reference herein where appropriate for appropriate teachings of additional or alternative details, features and/or technical background.

### SUMMARY OF THE INVENTION

An object of the invention is to solve at least the above problems and/or disadvantages and to provide at least the advantages described hereinafter.

The present invention provides a broadband gain medium, and a method for forming the same, that exhibits a broader gain spectrum than prior art semiconductor materials. The broadband gain medium of the present invention includes a multiple quantum well region made up of at least two quantum wells, with at least one of the quantum wells having a thickness and composition that vary as a function of position along the resonant cavity direction, and at least one quantum well having a thickness profile that is different than the other quantum wells.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIGS. 1A-1C are cross-sectional, perspective and plan schematic views, respectively, of a broadband gain medium, in accordance with one embodiment of the present invention;

FIGS. 2A-2C are schematic representations of the conduction and valence bands of a preferred multiple quantum well region used in the broadband gain medium of FIGS. 1A-1C, at three different points along the waveguide direction, in accordance with the present invention;

FIG. 2D is a schematic representation of the conduction and valence bands of one of the quantum wells in the Broadband gain medium of FIGS. 1A-1C, at three points along the waveguide direction, in accordance with the present invention; and

FIG. 3 is a schematic representation of a tunable laser utilizing the Broadband gain medium of the present invention.

### DETAILED DESCRIPTION OF PREFERRED EMBODIMENTS

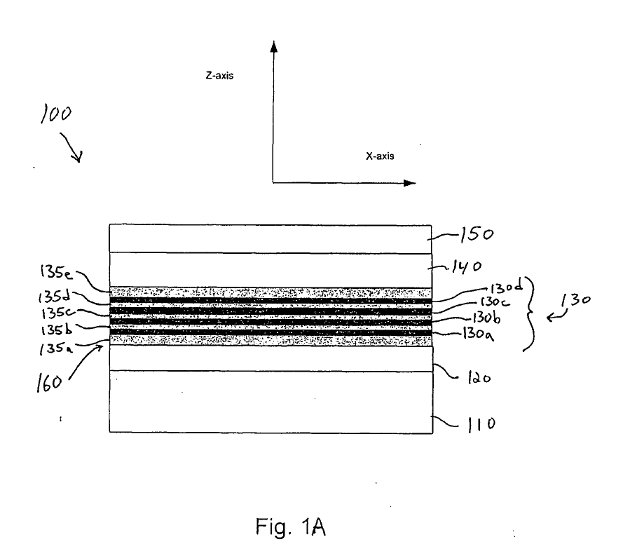

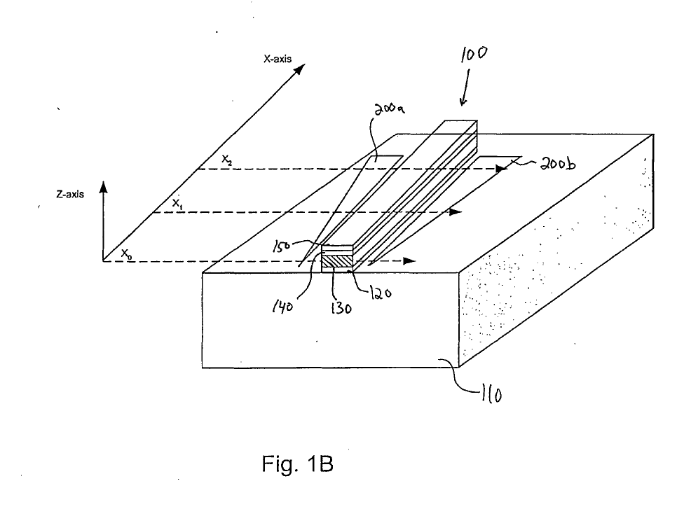

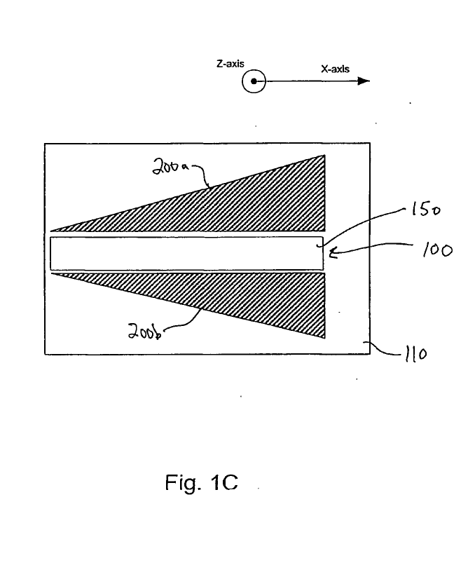

FIGS. 1A-1C are cross-sectional, perspective and plan schematic views, respectfully, of a broadband gain medium 100,in accordance with one embodiment of the present invention. The broadband gain medium 100 includes a substrate 110, a buffer layer 120, a MQW region 130, a cladding layer 140 and a contact layer 150.

In a preferred embodiment, the substrate 110 is an n-doped InP substrate, the buffer 120 is a n-doped InP buffer layer, the MQW region 130 is an InGaAs/InGaAsP MQW, the cladding layer 140 is a P-doped InP layer, and the contact layer is a P-doped InGaAs layer. However, other materials can be used for the substrate 110, the buffer layer 120, the MQW 130, the cladding layer 140 and the contact layer 150, while still falling within the scope of the present invention.

The MQW region 130 preferably comprises four quantum wells 130a-130d, preferably InGaAs quantum wells, separated by five barriers 135a-135e, preferably InGaAsP barriers, that are preferably formed using standard metalorganic chemical vapor deposition (MOCVD) techniques. At least one of the quantum wells 130a-130d has a non-constant “thickness profile” and a non-constant material composition that each vary as a function of position along the x-axis. The term “thickness profile”, as used herein, refers to the thickness of the quantum well (measured along the z-axis) at all positions along the resonant cavity direction (x-axis). Thus, a quantum well with a constant thickness profile has a substantially constant thickness along its entire length (along the x-axis), while a quantum well with a non-constant thickness profile has a thickness that changes as a function of position along the x-axis.

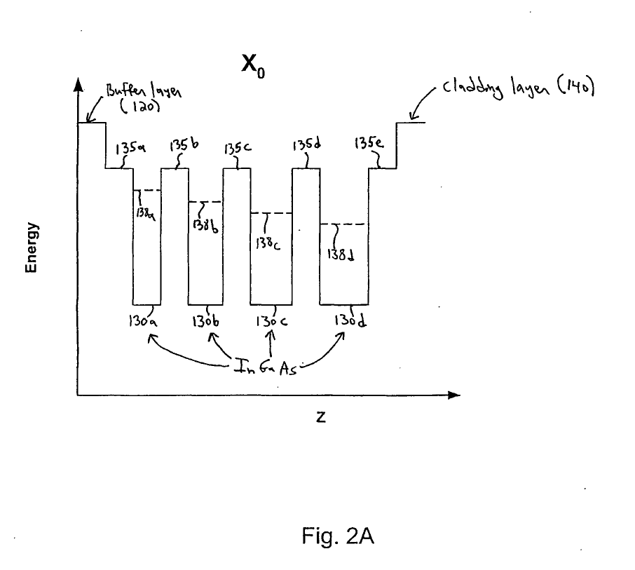

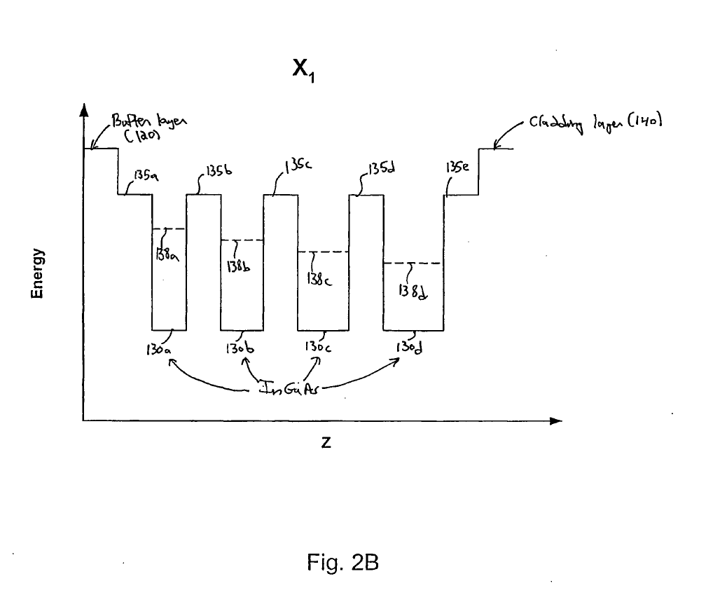

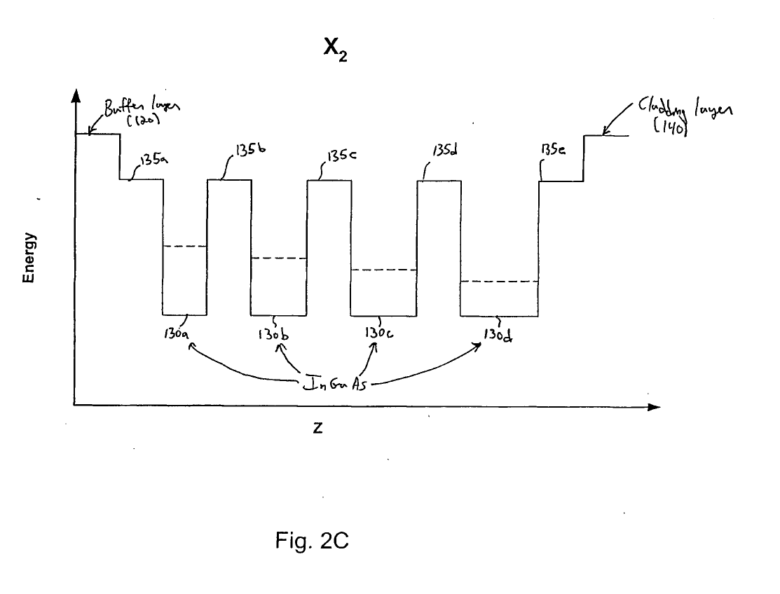

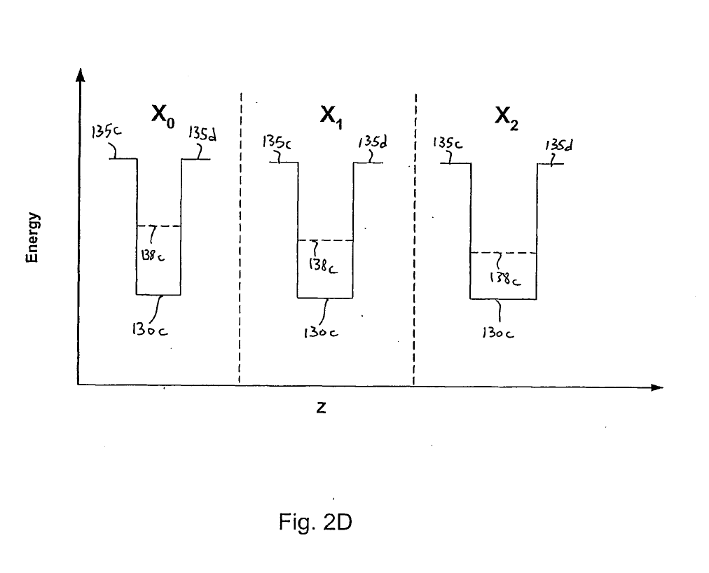

In a preferred embodiment, each of the quantum wells 130a-130d has a non-constant thickness profile, preferably a thickness that starts at an initial value at one end 160 of the MQW region 130, and that increases as a function of position along the x-axis, as well as a composition that varies as a function of position along the x-axis. Pot ease of illustration, the thickness increase along the x-axis is graphically shown only in FIGS. 2A-2D, which will be explained in more detail below.

Further, at least one of the quantum wells 130a-130d preferably has a different thickness profile than the other quantum wells. In a preferred embodiment, all the quantum wells 130a-130d each have different thickness profiles with respect to each other. Thus, each quantum well preferably has different thickness with respect to the other quantum wells at all points along the x-axis.

A non-constant thickness profile is preferably achieved by using selected area growth (SAG) techniques. With SAG, growth inhibition from a mask, preferably an SiO₂ mask, is used to enhance the growth rate in between the mask regions. During MOCVD, no deposition takes place on the mask, therefore growth rate enhancement occurs in the unmasked regions.

As shown in FIGS. 1B and 1C, a preferred mask for selected area growth of each of the quantum wells 130a-130d comprises a symmetric pair of tapered SiO₂ stripes 200a and 200b that are deposited and patterned on the substrate 110 using standard photolithographic techniques.

For a given separation between each of the SiO₂ stripes 200a and 200b, the width of the SiO₂ stripes determines the growth rate enhancement in the region between the stripes 200a and 200b. Because each SiO₂ stripe 200A and 200B is tapered, the quantum wells 130a-130d and barriers 135a-135e grown between the stripes 200A and 200B will exhibit a variation in thickness along their length for any predetermined growth time. This produces the non-constant thickness profile.

In addition, the width of the SiO₂ oxide stripes 200a and 200b determines the material composition of the quantum well layers and barrier layers grown between the stripes. In the case of an In₁₋ₓGaₓAs_{1-y}P_{y} barrier layer, the barrier layer becomes more Indium and Arsenide rich (smaller x and y) as the width of the SiO₂ oxide stripes 200a and 200b increases. In the case of an In₁₋ₓGaₓAs quantum well, the quantum well becomes more Indium rich (smaller x) as the width of the SiO₂ oxide stripes 200a and 200b increases.

The SiO₂ stripes 200a and 200b are shown in FIGS. 1B and 1C for illustrative purposes. It should be appreciated that the oxide stripes are removed after fabrication of the Broadband gain medium 100.

As discussed above, in addition to each quantum well having a non-constant thickness profile and a non-constant material composition, the growth time used for at least one of the quantum wells 130a-130d is different than the growth time used for the other quantum wells, so that at least one of the quantum wells has a different thickness profile than the other quantum wells. A quantum well with a different thickness profile than the other quantum wells will exhibit a different thickness than the other quantum wells at all points along the x-axis. In a preferred embodiment, a different growth time is used for each of the quantum wells 130a-130d, so that each quantum well exhibits a unique thickness profile.

The variation in thickness and material composition along the x-axis exhibited by each of the quantum wells, which is preferably obtained by using SAG growth techniques, results in a varying band gap as a function of position along the x-axis for each of the quantum wells 130A-130D. This, in turn, varies the wavelength of peak gain as a function of position along the x-axis, thereby producing a broader gain spectrum for the Broadband gain medium 100.

In addition to the broader gain spectrum caused by the non-constant thickness profile and non-constant material composition exhibited by each quantum well, varying the growth time of each quantum well so as to change the thickness profile of each quantum well also contributes to broadening of the optical gain spectrum of the broadband gain medium 100. This is because changing the thickness profiles will also vary the band gap, thus broadening the overall gain spectrum of the broadband gain medium 100.

The variation in the band gap of the quantum wells 130a-130d caused by each quantum well having a non-constant thickness profile and non-constant material composition, as well as each quantum well having a different thickness profile, is shown schematically in FIGS. 2A-2D. FIGS. 2A-2C are schematic representations of the conduction and valence bands of each quantum well, as a function of position along the z-axis, at positions X₀, X₁, and X₂ along the x-axis, respectively. FIG. 2D is a schematic representation of the conduction and valence bands of quantum well 130c, as a function of position along the z-axis, at x-axis positions X₀, X₁, and X₂.

As shown in FIG. 2A, at position X₀ along the x-axis (see FIG. 1B), each of the quantum wells 130a-130d exhibit a different thickness, with the quantum well 130a closest to the buffer layer 120 exhibiting the smallest thickness, and the other quantum wells 130b-130d exhibiting progressively larger thicknesses as they get closer to the cladding layer 140. This is the result of each quantum well having a different thickness profile.

The different quantum well thicknesses result in different valence band energies, with the narrowest quantum well 130a exhibiting the highest valence band energy 138a and the thickest quantum well 130d exhibiting the lowest valence band energy 138d. This results in each of the quantum wells 130a-130d providing a peak gain for a different respective wavelength band, which is determined by the respective valence band energy levels 138a-138d. The smaller the valence band energy, the longer the wavelength at which peak gain is provided.

As illustrated in FIGS. 2B and 2C, the thickness of each of the quantum wells 130a-130d gets progressively larger as one moves along the x-axis. This is because each of the quantum wells 130a-130d are preferably formed with a non-constant thickness profile, in which the thickness progressively increases along the x-axis. In addition, the material composition of each quantum well varies as a function of position along the x-axis, as discussed above.

This is also illustrated in FIG. 2D, which shows the conduction and valence bands for a single quantum well 130c at points X₀, X₁, and X₂ along the x-axis. As shown in FIG. 2D, each individual quantum well has a thickness that preferably increases along the x-axis, as well as a material composition that varies as a function of position along the x-axis. Thus, the valance band energy 138c of the quantum well 130c gets progressively lower along the x-axis.

In a preferred embodiment, quantum well 130a has a thickness that varies from approximately 2.4 nm to approximately 6.0 nm as a function of position along the x-axis, quantum well 130b has a thickness that varies from approximately 2.8 nm to approximately 7.0 nm as a function of position along the x-axis, quantum well 130c has a thickness that varies from approximately 3.2 nm to approximately 8.0 nm as a function of position along the x-axis, and quantum well 130d has a thickness that varies from approximately 3.6 nm to approximately 9.0 nm as a function of position along the x-axis.

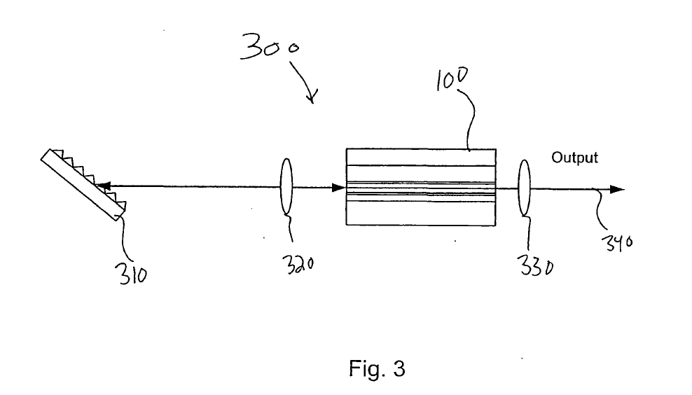

The broadband gain medium 100 of the present invention can be used to make a highly tunable laser, as shown in FIG. 3. The tunable laser 300 is an external cavity laser that includes the broadband gain medium 100, a grating 310 and lenses 320 and 330. Wavelength tuning of the laser output 340 is achieved by rotating the grating 310. The grating is one example of a wavelength tuning device that can be used to tune the wavelength of the tunable laser 300. It should be appreciated that other wavelength tuning devices, such as a Fabry-Perot filter, may be used while still falling within the scope of the present invention.

With the broad gain spectrum exhibited by the broadband gain medium 100 of the present invention, the tunable laser 300 can exhibit a very broad tuning range. With proper adjustment of the thickness of each quantum well along the x-axis, as well as the thickness profile of each quantum well, a tuning range as large as approximately 500 nm or more can be achieved.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art.

For example, although an InGaAs/InGaAsP multiple quantum well region has been described and illustrated as one embodiment, other types of multiple quantum well regions, such as InAlGaAs/InGaAs and AlGaSb/GaSb multiple quantum well regions, can be used while still falling within the scope of the present invention.

Further, the embodiment described and illustrated above includes four quantum wells, with each quantum well having a non-constant thickness profile. In addition, each of the quantum wells in the above-described embodiment exhibits a different thickness profile. It should be appreciated that any multiple quantum well region can be used, as long as at least one of the quantum wells has a non-constant thickness profile, and at least one of the quantum wells has a thickness profile that is different than the other quantum wells. For example, the present invention can be practiced in whole or in part by a multiple quantum well region that includes three quantum wells, with only one of the quantum wells having a non-constant thickness profile, and one of the quantum wells having a thickness profile that is different than the thickness profile of the other two quantum wells.

In addition, in the embodiment described and shown above, the non-constant thickness profile is obtained by using SAG fabrication techniques, and the thickness profile of each of the quantum wells is made different from the others by varying the growth time of each quantum well layer. However, other techniques known in the art for achieving these thickness parameters may be used while still falling within the scope of the present invention. In the claims, means-plus-function clauses are intended to cover the structures described herein as performing the recited function and not only structural equivalents but also equivalent structures.

1. A broadband gain medium, comprising:
a substrate; and
a multiple quantum well region on the substrate comprising at least two quantum wells, wherein at least one of the quantum wells exhibits a non-constant thickness profile and a non-constant material composition, and at least one of the quantum wells exhibits a thickness profile that is different than a thickness profile of the other quantum wells.

2. The broadband gain medium of claim 1, wherein the multiple quantum well region comprises an InGaAs/InGaAsP quantum well region.

3. The broadband gain medium of claim 1, wherein the multiple quantum well region comprises a plurality of InGaAs quantum wells, wherein respective InGaAsP layers are positioned between adjacent InGaAs quantum wells.

4. The broadband gain medium of claim 1, wherein the thickness profile of each quantum well is adjusted to broaden a gain spectrum of the broadband gain medium.

5. The broadband gain medium of claim 1, wherein each of the quantum wells has a non-constant thickness profile and a non-constant material composition.

6. The broadband gain medium of claim 1, wherein each quantum well has a different thickness profile.

7. The broadband gain medium of claim 1, wherein each quantum well has a different and non-constant thickness profile and a non-constant material composition.

8. The broadband gain medium of claim 5, wherein each quantum well has a thickness that increases along a resonant cavity direction.

9. The broadband gain medium of claim 7, wherein each quantum well has a thickness that increases along a resonant cavity direction.

10. A tunable semiconductor laser comprising the broadband gain medium of claim 1.

11. A broadband gain medium, comprising:
a substrate;
a buffer layer on the substrate;
a multiple quantum well region on the buffer layer comprising at least two quantum wells, wherein at least one of the quantum wells exhibits a non-constant thickness profile and a non-constant material composition, and at least one of the quantum wells exhibits a thickness profile that is different than a thickness profile of the other quantum wells;
a cladding layer on the multiple quantum well region; and
a contact layer on the cladding layer.

12. The broadband gain medium of claim 11, wherein the substrate comprises an n-doped InP substrate, the buffer layer comprises an n-doped InP buffer layer, the multiple quantum well region comprises an InGaAs/InGaAsP multiple quantum well region, the cladding layer comprises a p-doped InP layer, and the contact layer comprises a p-doped InGaAs layer.

13. The broadband gain medium of claim 11, wherein the multiple quantum well region comprises a plurality of InGaAs quantum wells, and respective InGaAsP layers positioned between adjacent InGaAs quantum wells.

14. The broadband gain medium of claim 11, wherein the multiple quantum well region comprises:
a first InGaAsP layer on the buffet layer;
a first InGaAs quantum well on the first InGaAsP layer;
a second InGaAsP layer on the first InGaAs quantum well;
a second InGaAs quantum well on the second InGaAsP layer;
a third InGaAsP layer on the second InGaAs quantum well;
a third InGaAs quantum well on the third InGaAsP layer;
a fourth InGaAsP layer on the third InGaAs quantum well;
a fourth InGaAs quantum well on the fourth InGaAsP layer; and
a fifth InGaAsP layer on the fourth InGaAs quantum well.

15. The broadband gain medium of claim 11, wherein each of the quantum wells has a non-constant thickness profile and a non-constant material composition.

16. The broadband gain medium of claim 11, wherein each of the quantum wells has a different thickness profile.

17. The broadband gain medium of claim 11, wherein each of the quantum wells has a different and non-constant thickness profile, and a non-constant material composition.

18. The broadband gain medium of claim 14, wherein each of the quantum wells has a thickness that increases along a resonant cavity direction.

19. The broadband gain medium of claim 18, wherein, for any point along the resonant cavity direction, the thickness of the second InGaAs quantum well is larger than the thickness of the first InGaAs quantum well, the thickness of the third InGaAs quantum well is larger than the thickness of the second InGaAs quantum well, and the thickness of the fourth InGaAs quantum well is larger than the thickness of the third InGaAs quantum well.

20. A tunable semiconductor laser comprising the broadband gain medium of claim 19.

21. A tunable semiconductor laser, comprising:
a broadband gain medium, comprising:
a substrate,
a buffer layer on the substrate,
a multiple quantum well region on the buffer layer comprising at least two quantum wells, wherein at least one of the quantum wells exhibits a non-constant thickness profile and a non-constant material composition, and at least one of the quantum wells exhibits a thickness profile that is different than a thickness profile of the other quantum wells,
a cladding layer on the multiple quantum well region, and
a contact layer on the cladding layer; and
a wavelength tuning device optically coupled to the broadband gain medium.

22. The tunable laser of claim 21, wherein the wavelength tuning device comprises a grating.

23. A method of fabricating a broadband gain medium, comprising the steps of:
growing at least two quantum wells by metalorganic chemical vapor deposition (MOCVD) selective area growth such that at least one of the quantum wells has a non-constant thickness profile and a non-constant material composition;
wherein a growth time for each of the quantum wells is adjusted such that a thickness profile of at least one of the quantum wells is different than a thickness profile of the other quantum wells.

24. The method of claim 23, wherein the step of growing at least two quantum wells by MOCVD selective area growth comprises the steps of:
forming an oxide mask on a substrate, wherein the oxide mask comprises first and second tapered oxide mask regions spaced apart on the substrate; and
subjecting the substrate to MOCVD, wherein a quantum well growth rate between the first and second tapered oxide regions varies as a function of the width of the first and second tapered oxide regions.

25. The method of claim 23, wherein at least one of the quantum wells is formed so that its thickness increases along a resonant cavity direction.

26. The method of claim 23, wherein four quantum wells are formed with respective thicknesses that increase along a resonant cavity direction.

27. A method of fabricating a semiconductor optical amplifier, comprising the steps of:
providing a substrate;
forming a buffer layer on the substrate;
growing a multiple quantum well region, comprising a plurality of quantum wells, on the buffet layer using metalorganic chemical vapor deposition (MOCVD) selective area growth, such that at least one of the quantum wells has a non-constant thickness profile and a non-constant material composition, wherein a growth time for each of the quantum wells is adjusted such that a thickness profile of at least one of the quantum wells is different than a thickness profile of the other quantum wells; and
forming a cladding layer on the multiple quantum well region.

28. The method of claim 27, wherein the step of forming a multiple quantum well region by MOCVD selective area growth comprises the steps of:
forming an oxide mask on the substrate, wherein the oxide mask comprises first and second tapered oxide mask regions spaced apart on the substrate; and
subjecting the substrate to MOCVD, wherein a quantum well growth rate between the first and second tapered oxide regions varies as a function of the width of the first and second tapered oxide regions.

29. The method of claim 27, wherein at least one of the quantum wells is selectively grown so that its thickness increases along a resonant cavity direction.

30. The method of claim 27, wherein four quantum wells are selectively grown with respective thicknesses that increase along a resonant cavity direction.
